(19) United States
(12) Patent Application Publication
(10) Pub. No.: US 2009/0017206 A1
(43) Pub. Date: Jan. 15, 2009

(54) METHODS AND APPARATUS FOR REDUCING THE CONSUMPTION OF REAGENTS IN ELECTRONIC DEVICE MANUFACTURING PROCESSES

(75) Inventors: Daniel O. Clark, Pleasanton, CA (US); Robert Z. Bachrach, Burlingame, CA (US); Mehran Moalem, Cupertino, CA (US); Jay J. Jung, Sunnyvale, CA (US)

Correspondence Address: DUGAN & DUGAN, PC, 245 Saw Mill River Road, Suite 309, Hawthorne, NY, 10532, US

(73) Assignee: Applied Materials, Inc., Santa Clara, CA (US)

(21) Appl. No.: 12/140,055

(22) Filed: Jun. 16, 2008

Related U.S. Application Data
(60) Provisional application No. 60/944,487, filed on Jun. 16, 2007.
(60) Provisional application No. 60/988,771, filed on Nov. 16, 2007.
(60) Provisional application No. 61/026,432, filed on Feb. 5, 2008.
(60) Provisional application No. 61/039,101, filed on Mar. 24, 2008.
(60) Provisional application No. 61/052,164, filed on May 9, 2008.

(51) Int. Cl. C23C 16/44; C23C 16/54

(52) U.S. Cl. 427/248.1; 118/722

(57) ABSTRACT

A substrate coating system is provided which includes a substrate coating chamber; a gas box connected to the coating chamber and adapted to provide reagent gases to the coating chamber; and a reagent reclaim system connected to the substrate coating chamber and the gas box, wherein the reagent reclaim system includes a wet scrubber connected to the coating chamber; a polisher connected to the wet scrubber; and a dryer connected to the polisher and the gas box.

The present application claims priority to U.S. Provisional Patent Application Ser. No. 60/944,487, filed Jun. 16, 2007 and entitled “SYSTEMS AND METHODS OF H₂ EFFLUENT RECYCLING FOR SOLAR ABATEMENT APPLICATIONS” (Attorney Docket No. 12189/L), which is hereby incorporated herein by reference in its entirety for all purposes.

The present application claims priority to U.S. Provisional Patent Application Ser. No. 60/988,771, filed Nov. 16, 2007 and entitled “SYSTEMS AND METHODS OF H₂ EFFLUENT RECYCLING FOR SOLAR ABATEMENT APPLICATIONS” (Attorney Docket No. 12189/L2), which is hereby incorporated herein by reference in its entirety for all purposes.

### RELATED APPLICATIONS

Co-owned U.S. patent application No. 61/052,164, filed May 9, 2008 and entitled “METHODS AND APPARATUS FOR REDUCING THE CONSUMPTION OF REAGENTS IN ELECTRONIC DEVICE MANUFACTURING PROCESSES” (Attorney Docket No. 13543), is hereby incorporated by reference herein in its entirety and for all purposes.

Co-assigned U.S. patent application Ser. No. 11/565,400 filed Nov. 30, 2006, and entitled “Dilution Gas Recirculation”, (Attorney Docket No. 11402), is hereby incorporated herein by reference in its entirety for all purposes.

Co-assigned U.S. Patent Application No. 61/039,101, filed Mar. 24, 2008, and entitled “METHODS FOR USING REDUCED PURITY SILANE TO DEPOSIT AMORPHOUS AND MICROCRYSTALLINE SILICON”, (Attorney Docket No. 13226/L), is hereby incorporated herein by reference in its entirety for all purposes.

Co-assigned U.S. Patent Application No. 61/026,432, filed Feb. 5, 2008, and entitled “Abatement Systems”, (Attorney Docket No. 13208/L2), is hereby incorporated herein by reference in its entirety for all purposes.

### FIELD OF THE INVENTION

The present invention relates generally to electronic device manufacturing and is more particularly directed to the reclaim and recycle of reagent gases which are used in substrate coating processes.

### BACKGROUND OF THE INVENTION

Some electronic device manufacturing processes may use large quantities of expensive reagents and some of these reagents may be harmful and/or hazardous if released to the atmosphere. It is known to abate these reagents and their byproducts through the use of abatement systems which convert the reagents or their byproducts into less harmful and/or hazardous compounds. The abatement of these reagents and their byproducts may address the issue of the harmful and/or hazardous nature of the reagents/byproducts.

Abatement may not, however, address the fact that a significant quantity of expensive reagents may be purchased and eventually abated when the reagents pass unused through a process chamber.

It is desirable to develop methods and apparatus which would reduce the amount of expensive reagents which are abated.

### SUMMARY OF THE INVENTION

In one aspect the invention provides a substrate coating system which includes 1) a substrate coating chamber; 2) a gas box connected to the coating chamber and adapted to provide reagent gases to the coating chamber; and 3) a reagent reclaim system connected to the substrate coating chamber and the gas box, wherein the reagent reclaim system includes a) a scrubber connected to the coating chamber; a polisher connected to the scrubber; and a dryer connected to the polisher and the gas box.

In another aspect the invention provides a substrate coating system which includes 1) a substrate coating chamber; 2) a gas box connected to the coating chamber and adapted to provide reagent gases to the coating chamber; and 3) a reagent reclaim system connected to the substrate coating chamber and the gas box, wherein the reagent reclaim system includes a) a reagent filter connected to the coating chamber; and b) a dopant filter connected to the reagent filter.

In yet another aspect, the invention provides a method of operating a substrate coating system which includes a) supplying more than one reagent to a substrate coating chamber; b) coating a substrate in the substrate coating chamber; c) exhausting unused reagents from the substrate coating chamber; and d) reclaiming a reagent for reuse as a reagent in the substrate coating chamber.

Numerous other aspects are provided in accordance with these and other aspects of the invention. Other features and aspects of the present invention will become more fully apparent from the following detailed description, the appended claims and the accompanying drawings.

### BRIEF DESCRIPTION OF THE DRAWINGS

FIG. 1 is a schematic depiction of a substrate coating system of the invention which is adapted to recycle hydrogen gas.

FIG. 1A is a schematic depiction of another embodiment of the system of FIG. 1.

FIG. 2 is a schematic depiction of another apparatus of the invention for recycling hydrogen gas and reclaiming silicon.

FIG. 3 is a schematic depiction of a substrate coating system of the invention which includes a co-generation apparatus.

FIG. 4 is a schematic depiction of another embodiment of the system of FIG. 1.

FIG. 5 is a schematic depiction of another embodiment of the system of FIG. 2.

### DETAILED DESCRIPTION

Electronic device manufacturing processes may use large amounts of reagents, such as silane and hydrogen. A substantial portion of these reagents which may be expensive and/or scarce may pass from a process chamber unused, to be treated as waste.

In a typical substrate coating process prior to the invention, silane and hydrogen gases may be introduced into a substrate coating chamber under substrate coating process conditions. A significant amount of the hydrogen and silane may pass through the substrate coating chamber unused. It is known to treat the unused hydrogen and silane as harmful and/or dangerous effluent and to abate the effluent in a suitable abatement unit. Such an abatement unit may be a thermal abatement unit in which the effluent is heated and mixed with an oxidant to oxidize the effluent.

Silane may be expensive and difficult to obtain in the future. In addition, some electronic device manufacturing fabrication plants may be located in relatively remote locations where it is difficult or expensive to truck or pipe in reagents. It would be desirable to reuse these reagents so that only lesser amounts may need to be obtained from suppliers and lesser amounts may need to be treated as waste.

In one aspect, the present invention provides methods and apparatus for reclaiming hydrogen for reuse as a reagent in a substrate coating process. This may be accomplished by taking a stream of unused reagent from the substrate coating chamber and scrubbing it to remove impurities. The scrubbed unused reagent stream may then be passed through a cold trap or a refrigerated chiller to further purify the unused reagent stream. Next, the unused reagent stream may be passed through a dryer to remove water which may be present in the unused reagent stream. The unused reagent stream may then be passed back to a gas box from which it may be supplied to the substrate coating chamber as a reagent.

In another aspect, the present invention provides methods and apparatus for reclaiming hydrogen for reuse as a reagent in a substrate coating process, and for reclaiming silicon for use in the manufacture of silane, which silane may then be used as a reagent in the substrate coating process. This may be accomplished by taking a stream of unused reagent from the substrate coating chamber and passing it through a silicon filter to remove silicon, silane, di-silane, tri-silane, and poly-silane from the unused reagent stream. In addition, to remove any dopants which may be present in the unused reagent stream, the unused reagent stream may be passed through a dopant filter, or an adsorption or absorption separation matrix. The unused reagent stream that has been passed through the filters may then consist primarily of hydrogen which may be passed to a gas box from which it may be sent to the substrate coating chamber for reuse.

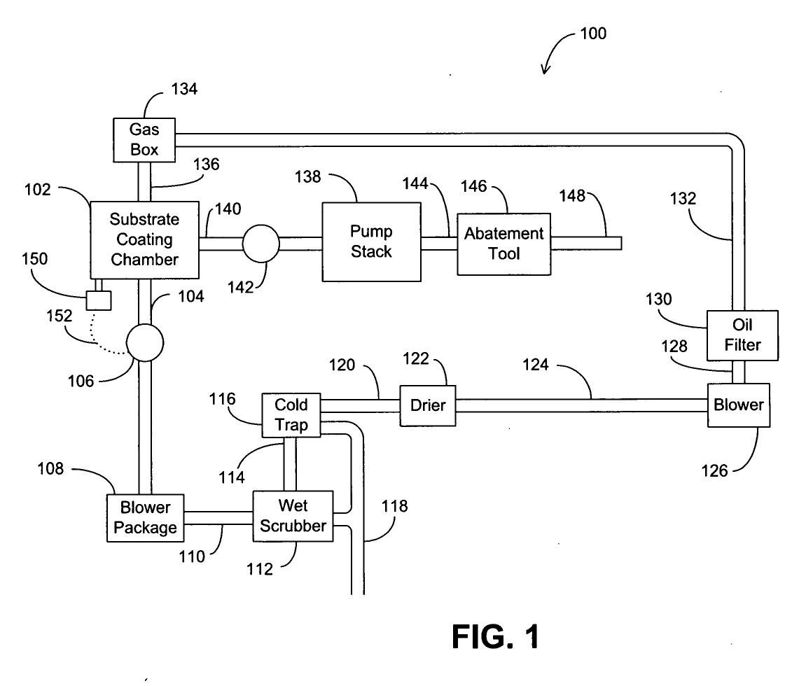

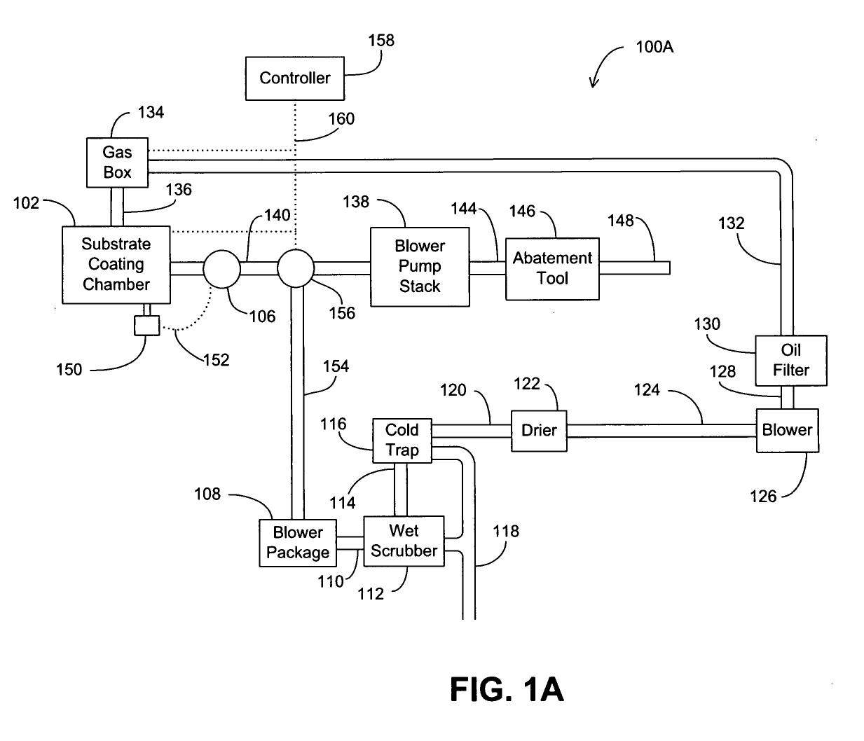

FIG. 1 is a schematic drawing of an substrate coating system 100 of the present invention useful for reclaiming and reusing hydrogen as a reagent in a substrate coating process. System 100 may include a substrate coating chamber 102 which may be used to coat substrates. For example, in the production of solar panels, it is common to coat a substrate such as glass with silicon to form a polysilicon coating on the glass. Substrates other than glass may be used, for example, metals, films, polymers, etc. System 100 may be used in coating processes other than the production of solar panels.

Substrate coating chamber 102 may be connected through conduit 104 and throttle valve 106 to blower package 108. Blower package 108 may include low pressure water cooled blowers, although non-water cooled blowers may be used. The blowers may be lower tolerance blowers and may provide the benefits of less energy being needed to run the blowers and less heat being transferred to the gasses being moved by the blowers. In embodiments wherein more than one blower (optionally water cooled) may be used in blower package 108, the blowers may be staged so as to increase the pressure of the recycle stream while imparting a reduced amount of heat to the recycle stream. Any blowers or pumps which can increase the pressure of the recycle stream to, for example, between about 10 to about 40 p.s.i., about 20 to about 30 p.s.i. or about 10 to about 20 p.s.i., may be used. Other higher and lower pressures may be used. The blowers may reduce or eliminate the transmission of any back pressure waves from downstream of the blower package 108 to upstream of the blower package 108.

Blower package 108 may be connected through conduit 110 to wet scrubber 112. Scrubber 112 may be, for example, a bubble tower, burr saddle, packed bed tower, or scrubbing tower. Any suitable wet scrubber may be used.

Scrubber 112 may be connected through conduit 114 to cold trap 116. Cold trap 116 may include one or more refrigerated plates or other surfaces upon which gases which are to be removed from a gas stream may condense. The cold trap 116 may be adapted to be isolated and bypassed to facilitate maintenance.

Scrubber 112 and cold trap 116 may be connected to a water treatment unit (not shown) through conduit 118. Cold trap 116 may be connected through conduit 120 to dryer 122. The dryer 122 may be a molecular sieve dryer, or any other suitable dryer. The dryer 122 may be a single or a multiple bed dryer.

The dryer 122 may be connected through conduit 124 to blower 126. Blower 126 may be similar to a blower used in the blower package 108. Blower 126 may be connected through conduit 128 to oil filter 130. Oil filter 130 may be used to trap any oil, contaminant, lubricant reaction products, and or any other high vapor pressure material which may be imparted to the reagent stream from blower stack 126.

Oil filter 130 may be connected through conduit 132 to gas box 134. The gas box 134 may be used to mix reagent and other gases for introduction through conduit 136 into substrate coating chamber 102. The gas box 134 may be configured such that it is connected to reagent sources (not shown) and other gas sources (not shown). The reagent and other gases may be introduced into the gas box through mass flow controllers (not shown) so that precise mass flow rates of reagent and other gases may be introduced.

The substrate coating chamber 102 may also be connected to pump stack 138 through conduit 140 and or isolation valve 142. The pump stack 138 may be connected through conduit 144 to abatement tool 146.

The abatement tool 146 may be a burn wet abatement tool, or an electro thermal abatement unit, etc. Any abatement tool which is effective to abate chamber cleans may be used. The abatement tool 146 may be connected through conduit 148 to a house exhaust system (not shown), further abatement treatment on (not shown), or to the atmosphere.

Chamber pressure control gauge 150 may be connected to substrate coating chamber 102 and may also be connected to throttle valve 106 through communication line 152.

In operation, the substrate coating chamber 102 may be operated in two modes. In a first mode, the substrate coating chamber 102 may perform a coating process whereby a substrate is coated with, for example, silicon. In a second mode, the substrate coating chamber 102 may be cleaned with a plasma, such as a fluorine plasma.

The following description of the operation of system 100 uses a silicon coating on a substrate as an example. It should be understood, however, that the invention is not limited to coating silicon on a substrate, but, rather, may be used in any electronic device manufacturing process where a reagent may pass unused through a process chamber. Examples include deposition applications for solar panels, liquid crystal displays, organic light emitting diodes, film, and nanomanufacturing, etc. In addition, the invention may be used for process chambers which may be used to etch patterns to remove unwanted materials and/or to clean surfaces, etc.

In the first mode, the deposition mode, the gas box 134 may supply hydrogen and silane gases to the substrate coating chamber 102. During the coating process, the pressure in the substrate coating chamber 102 may be regulated by pressure gauge 150 and a combination of the throttle valve 106, the pump stack 108, and gas additions to the process chamber 102 from the gas box 138. The blower package 108 may provide a source of vacuum through conduit 104. Thus, during the coating process, an excess hydrogen and silane gas stream may be evacuated by blower package 108 from the substrate coating chamber 102 through conduit 104, throttle valve 106 and conduit 110, and passed into scrubber 112. The unused hydrogen and silane reagents may contact water in scrubber 112 which may have the effect of removing silane, di-silane, tri-silane, and poly-silane from the gas stream. In addition, scrubber 112 may remove dopants which may exist in the gas stream. The silane, di-silane, tri-silane, poly-silane, and dopants may exit the scrubber in scrubber medium through conduit 118. The remaining gas stream may then pass through conduit 114 into cold trap 116. The cold trap 116 may have the effect of removing any remaining particles, water, silane, di-silane, tri-silane, poly-silane, and dopants, which may remain in the gas stream. The gas stream may pass from the cold trap 116 through conduit 120 into dryer 122, where the gas stream may be dried to less than about 2 ppm water. Blower 126 may then motivate the gas stream to move from dryer 122 through conduits 124, 128 and oil filter 130 where any oil or other high molecular weight and/or high vapor pressure species which may have been imparted to the gas stream from blower 126 and/or blower 108 may be removed. At this stage, the gas stream may be a high purity stream of hydrogen gas which may then be inserted into gas box 134 for reuse as a reagent in the substrate coating process conducted in substrate coating chamber 102.

In the second mode, the cleaning mode, the substrate coating chamber may be cleaned with a plasma from a remote plasma source (not shown). This plasma clean may be motivated by pump stack 138 to move through conduit 140, isolation valve 142 and conduit 144 into abatement tool 146, where the plasma clean may be abated. From the abatement tool 146, the abated plasma clean may pass through conduit 148 into a house scrubber (not shown), further abatement (not shown), or to the atmosphere.

FIG. 1A is a schematic drawing of an alternative configuration of the substrate coating system 100 of FIG. 1, substrate coating system 100A. System 100A may be similar to system 100 of FIG. 1 with the exception of the connection between the blower package 108 and the substrate coating chamber 102, and the inclusion of a control system. Instead of the blower package 108 being connected directly to the substrate coating chamber 102, as depicted in FIG. 1, the blower package 108 may be connected through conduit 154 and three way valve 156 to conduit 140. Conduit 140 may be a vacuum line which connects pump stack 138 to the substrate coating chamber 102. Controller 158 may be connected through signal lines 162 the gas box 134, the substrate coating chamber 102, and the three way valve 156.

In operation, system 100A may operate similarly to system 100 of FIG. 1, with the exception that during the coating or deposition mode, unused reagent gases may not pass into conduit 104 as the reagent gases may in the system 100 of FIG. 1. Instead, the reagent gasses may pass into conduit 140, and then be diverted by valve 156 through conduit 154 into blower package 108. During the chamber clean mode, the valve 156 may be configured such that the chamber clean may pass through conduit 140 into pump stack 138.

The controller 158 may determine whether the substrate coating chamber 102 is in the clean mode or in the deposition mode, and may appropriately configure three way valve 156.

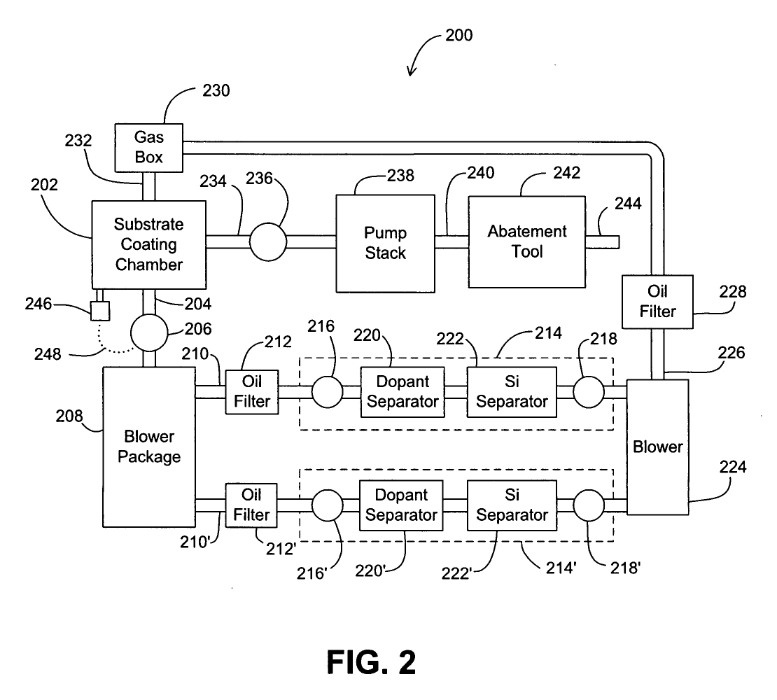

FIG. 2 is a schematic drawing of a substrate coating system 200 depicting another embodiment of the present invention. System 200 may include a substrate coating chamber 202 may be used to coat substrates. The substrate coating chamber 202 may be similar to the substrate chamber 102 of FIG. 1. The substrate coating chamber 202 which may be connected through conduit 204 and throttle valve 206 to blower package 208.

Blower package 208 may be similar to blower package 108 of FIG. 1.

Blower package 208 may be connected through conduits 210, 210′ and oil filters 212, 212′ to separation systems 214, 214′. Oil filters 212, 212′ may be similar to oil filter 130 of FIG. 1. Although two separation systems 214, 214′ are shown in FIG. 2, it is to be understood that fewer or more separation systems may be used (e.g., 1, 3, 4, etc.).

Separation system 214 may include isolation valves 216, 218; dopant separator 220; and silicon separator 222. Isolation valves 216, 218 may be used to isolate separation system 214 from system 200. Dopant separator 220 may be an absorption separation matrix or an adsorption separation matrix. Alternatively, the dopant separator 220 may be replaced with a dopant filter (not shown). Similarly, the silicon separator 222 may be an absorption separation matrix or an adsorption separation matrix, or, alternatively, silicon separator 222 may be a silicon filter. A suitable filter may be a honeycomb ceramic matrix which is coated with silicon. The ceramic may be an yttria doped alumina. Separation system 214′ may be similar to separation system 214.

Separation systems 214, 214′ may be connected to blower 224. Blower 224 may be connected through conduit 226 and oil filter 228 to gas box 230. Gas box 230 may be connected through conduit 232 to substrate coating chamber 202.

Substrate coating chamber 202 may also be connected through conduit 234 and isolation valve 236 to pump stack 238. Pump stack 238 may be connected through conduit 240 to abatement tool 242. Abatement tool 242 May be connected through conduit 244 to a house exhaust system (not shown), further abatement treatment (not shown), or to the atmosphere, etc.

Pressure gauge 246 may be connected to substrate coating chamber 202 and two throttle valve 206 by signal line 248.

Although not shown, system 200 may be modified in a way similar to the way system 100 may be modified to form system 100A. Such a modification would replace isolation valve 236 with a three way valve, which would be adapted to divert gas flow between the pump stack 238 and the blower package 208, depending upon whether the chamber was in a clean mode or a deposition mode, respectively. A controller such as the controller in system 100A may also be used.

In operation, substrate coating chamber 202 may operate similarly to substrate coating chamber 102 of FIG. 1, with the exception that in the deposition mode the unused reagents may not be passed through a wet scrubber, a cold trap, and a dryer, as they are in system 100 of FIG. 1.

Instead, the unused reagents (and any dopants) may be passed from blower package 208 through conduits 210, 210′, through oil filters 212, 212′ and into separation systems 214, 214′.

Separation systems 214, 214′ may remove dopants from the unused reagent gas stream with dopant separators 220, 220′, which, as described above, may be absorption or adsorption separation matrices. The dopants may be collected, separated if necessary, and reused as dopants.

Separation systems 214, 214′ may remove silicon compounds from the unused gas stream using silicon separation units 222, 222′. Silicon separators 222, 222′ may remove silicon, silane, di-silane, tri-silane, and poly-silane through mechanisms of absorption, adsorption, and/or filtration. The silicon, silane, di-silane, tri-silane, and poly-silane which may be removed from the unused reagent gas stream may be collected and sent, or sent directly, to a silane manufacturing unit, which may supply silane to the gas box 230 for use as a substrate in substrate coating chamber 202.

The net result of the unused reagent gas stream passing through separation systems 214, 214′ may be that the unused reagent gas which flows from the separation systems 214, 214′ into blower 224 may include high purity hydrogen gas. The high purity hydrogen gas may flow through conduit 226 and oil filter 228 (where any oil or other high molecular weight contaminant introduced into the hydrogen gas by blower 224 may be removed), and into gas box 230.

The remainder of the system 200 of FIG. 2 may operate similarly to the system 100 of FIG. 1.

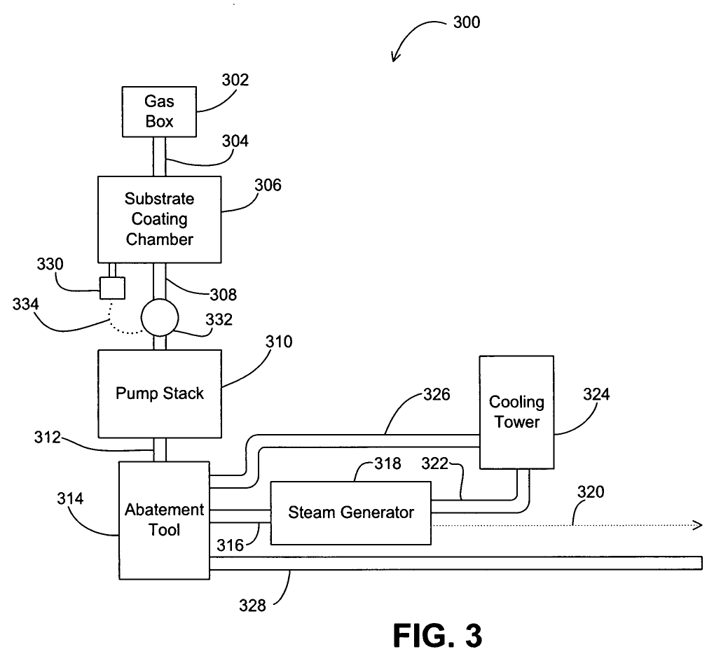

FIG. 3 is a schematic drawing depicting a substrate coating system 300 of the invention which includes a co-generation apparatus. System 300 may include gas box 302 which may be connected through conduit 304 to substrate coating chamber 306. The substrate coating chamber 306 may be similar to the substrate coating chambers discussed above with reference to the previous figures. Substrate coating chamber 306 may be connected through conduit 308 to pump stack 310. The pump stack 310 may be connected through conduit 312 to abatement tool 314. Abatement tool 314 may be connected through conduit 316 to steam generator 318. The steam generator 318 may be connected through conduit 322 to cooling tower 324. The steam generator may also be connected to a power grid or storage unit through electrical wire 320. The cooling tower 324 may be connected through conduit 326 to the abatement tool 314. Abatement tool 314 may be connected through conduit 328 to a house exhaust (not shown), further abatement treatment (not shown), or to the atmosphere. Pressure gauge 330 may be connected to the substrate coating chamber 306 and to the throttle valve 332 through signal line 334.

In operation the gas box 302 may provide reagent and other gases through conduit 304 to the substrate coating chamber 306. The substrate coating chamber 306 may operate similarly to the substrate coating chambers described with respect to the previous figures. During both deposition and chamber clean modes, effluent from the substrate coating chamber which may contain high levels of hydrogen and silane, may be evacuated from the substrate coating chamber through conduit 308 and throttle valve 332 by pump stack 310. The effluent may then flow through conduit 312 into abatement tool 314 where the effluent may be burned. In addition, the burned effluent may be contacted with cooling water in the abatement tool 314 to produce steam which may be exhausted through conduit 316 into steam generator 318. The steam generator 318 may generate electricity which may pass through electrical wire 320 to a power grid (not shown) or to an electrical storage device (not shown). The steam generator 318 may send hot water (which may include condensed steam) and steam through conduit 322 to cooling tower 324, were the hot water and steam may be cooled to form cooled water. The cooled water may be returned from the cooling tower 324 through conduit 326 to the abatement tool 314, where the cooled water may be used to cool the burned effluent and regenerate steam. Effluent from the abatement tool 314, which effluent may include oxidized unused reagents and oxidized chamber clean, may be sent through conduit 328 to a house exhaust (not shown), further abatement treatment (not shown), or to the atmosphere.

The operating pressure inside of the substrate coating chamber may be controlled by a combination of the pressure gauge 330, the throttle valve 332, the pump stack 310, and the addition of gases from the gas box 302.

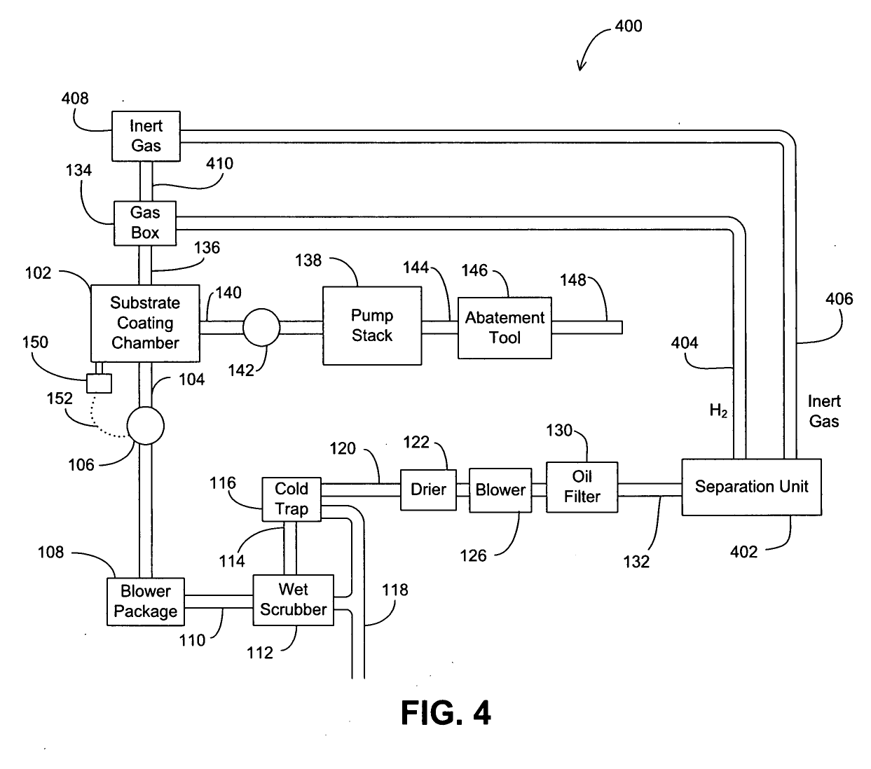

FIG. 4 is a schematic depiction of a substrate coating system 400. System 400 may be similar to the system 100 of FIG. 1, with the following exceptions. In system 400, the oil filter 130 may not be connected through conduit 132 to gas box 134 as it is in the system 100 of FIG. 1. Instead, the oil filter 130 may be connected through the conduit 132 to separation unit 402. The separation unit 402 may be a membrane separator which may be adapted to separate hydrogen gas from an inert gas. Any suitable separator may be used. The separation unit 402 may be connected through conduit 404 to the gas box 134 and through conduit 406 to inert gas source 408. The inert gas source 408 may be connected through the conduit 410 to the gas box 134.

In operation, the system 400 may operate similarly to the operation of system 100 of FIG. 1, with the following exceptions. In the system 400, inert gas may be introduced into the gas box 134 from the inert gas source 408 through the conduit 410. The inert gas may be nitrogen, helium, argon, etc. or any other suitable inert gas. The inert gas may be used to cool the substrate coating chamber 102. An additional benefit may be more efficient utilization of reagents such as silane and hydrogen. The inert gas may pass with the unused reagents through the system until the inert gas enters conduit 132 with otherwise highly pure hydrogen gas. The inert gas/hydrogen gas mixture may then enter separation unit 402 which may separate the hydrogen gas from the inert gas. The hydrogen gas may then pass from the separation unit 402 through the conduit 404 and into the gas box 134. The inert gas may pass from the separation unit 402 through the conduit 406 into the inert gas box 408, from which it may be sent through the conduit 410 into the gas box 134.

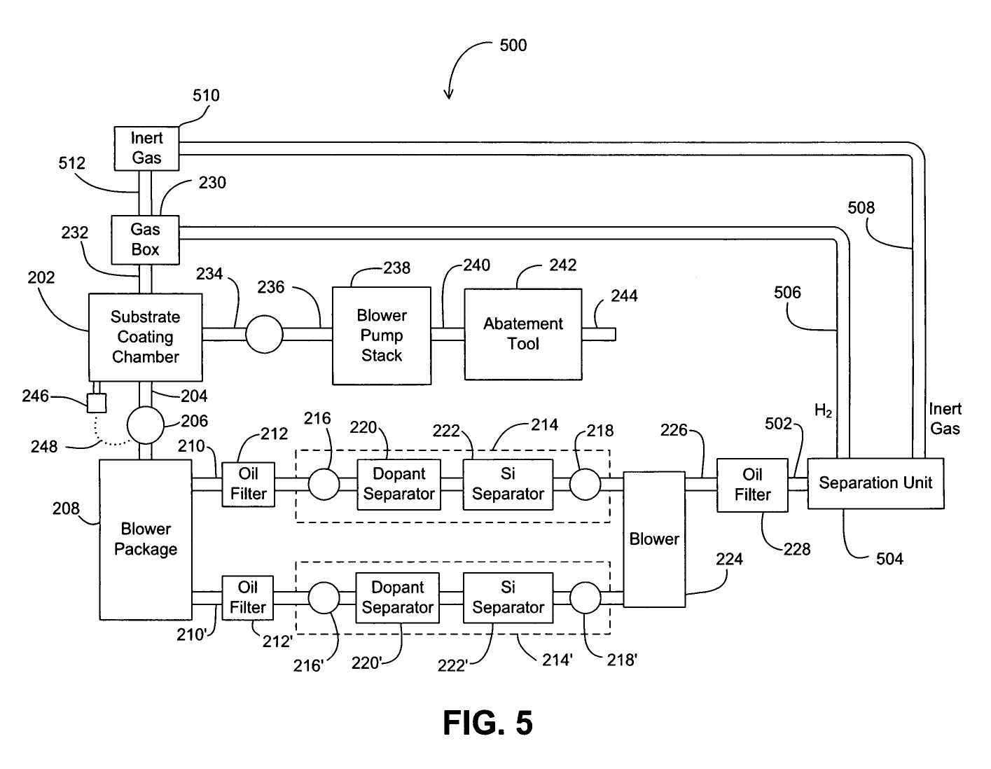

FIG. 5 is a schematic depiction of a substrate coating system 500. System 500 may be similar to the system 200 of FIG. 2, with the following exceptions. In system 500, the oil filter 228 may not be connected through the conduit 226 to the gas box 230 as it is in system 200 of FIG. 2. Instead, the oil filter 228 may be connected through conduit 502 to separation unit 504. The separation unit 504 may be similar to the separation unit 402 of FIG. 4. The separation unit 504 may be connected through conduit 506 to the gas box 230. The separation unit 504 may also be connected through the conduit 508 to inert gas source 510. The gas source 510 may be connected through conduit 512 to gas box 230.

In operation, the system 500 may operate similarly to the operation of the system 200 of FIG. 2, with the following exceptions. In the system 500, inert gas may be introduced into the gas box 134 from the inert gas source 510 through the conduit 512. As in the system 400 of FIG. 4, the inert gas may be nitrogen, helium, argon, etc. or any other suitable inert gas. The inert gas may have the same effects on the system 500 as the inert gas has on the system 400 of FIG. 4. As in the system 400, the inert gas may pass with the unused reagents through the system until the inert gas enters the conduit 502 with otherwise highly pure hydrogen gas. The inert gas/hydrogen gas mixture may then enter the separation unit 504 which may separate the hydrogen gas from the inert gas. The hydrogen gas may then pass from the separation unit 504 through the conduit 506 into the gas box 230. The inert gas may pass from the separation unit 504 through the conduit 508 into the inert gas source 510 from which the inert gas may be sent through the conduit 512 into the gas box 230.

The foregoing description discloses only exemplary embodiments of the invention. Modifications of the above disclosed apparatus and methods which fall within the scope of the invention will be readily apparent to those of ordinary skill in the art. For example, in the systems 400 and 500, the unused reagent gas may pass through a vacuum line and three-way valve as the unused reagent gases do in system 100A. Such modified systems may have control systems which divert effluent from the process chamber to either be recycled or abated depending upon whether the process chamber is in a deposition or in a chamber clean mode.

The invention claimed is:

1. A substrate coating system comprising:
a substrate coating chamber;
a gas box connected to the coating chamber and adapted to provide reagent gases to the coating chamber; and
a reagent reclaim system connected to the substrate coating chamber and the gas box, wherein the reagent reclaim system comprises:
a wet scrubber connected to the coating chamber;
a polisher connected to the scrubber; and
a dryer connected to the polisher and the gas box.

2. The substrate coating system of claim 1 further comprising a blower package located between the substrate coating chamber and the scrubber.

3. The substrate coating system of claim 1 wherein the polisher comprises a cold trap.

4. The substrate coating system of claim 1 wherein the polisher comprises a refrigerated chiller.

5. The substrate coating system of claim 1 wherein the dryer comprises a molecular sieve dryer.

6. The substrate coating system of claim 1 further comprising a blower and an oil filter located between the dryer and the gas box.

7. The substrate coating system of claim 1 further comprising a pump stack connected to the substrate coating chamber and an abatement tool connected to the pump stack.

8. The substrate coating system of claim 7 wherein the scrubber is connected to the coating chamber through a vacuum line which connects the pump stack to the substrate coating chamber.

9. A substrate coating system comprising:
a substrate coating chamber;
a gas box connected to the coating chamber and adapted to provide reagent gases to the coating chamber; and
a reagent reclaim system connected to the substrate coating chamber and the gas box, wherein the reagent reclaim system comprises:
a reagent filter; and
a dopant filter.

10. The substrate coating system of claim 9 wherein the reagent filter comprises one of a silicon filter, an adsorption separation matrix and an absorption separation matrix.

11. The substrate coating system of claim 10 wherein the reagent filter is heated.

12. The substrate system of claim 9 wherein the dopant filter comprises an adsorption separation matrix and an absorption separation matrix.

13. The substrate system of claim 12 wherein the dopant filter is heated.

14. The substrate coating system of claim 9 further comprising a blower package located between the reagent filter and the substrate coating chamber.

15. The substrate coating system of claim 9 further comprising a blower and an oil filter located between the dopant filter and the gas box.

16. A method of operating a substrate coating system comprising:
supplying more than one reagent to a substrate coating chamber;
coating a substrate in the substrate coating chamber;
exhausting unused reagents from the substrate coating chamber; and
reclaiming a reagent for reuse as a reagent in the substrate coating chamber.

17. The method of claim 16 wherein reclaiming the reagent for reuse as a reagent in the substrate coating chamber comprises scrubbing the unused reagents to remove impurities.

18. The method of claim 17 further comprising using a cold trap to remove impurities which remain in the unused reagents following the scrubbing.

19. The method of claim 17 further comprising drying the scrubbed unused reagents.

20. The method of claim 19 further comprising supplying the dried, scrubbed, unused reagents to a gas box which is adapted to supply more than one reagent to the substrate coating chamber.

21. The method of claim 16 wherein reclaiming a reagent for reuse as a reagent in the substrate coating chamber comprises filtering silicon from the unused reagents.

22. The method of claim 21 further comprising filtering dopants from the unused reagents.

23. The method of claim 21 further comprising using the filtered silicon to manufacture silane for use as a reagent in the substrate coating chamber.

24. The method of claim 21 further comprising sending the unused reagents from which silicon has been filtered to a gas box for reuse as a reagent in the substrate coating chamber.
